(19) United States
(12) Patent Application Publication
(10) Pub. No.: US 2025/0329619 A1
(43) Pub. Date: Oct. 23, 2025

(54) SEMICONDUCTOR PACKAGE AND PACKAGE MODULE INCLUDING THE SAME

(71) Applicant: Samsung Electronics Co., Ltd., Suwon-si (KR)

(72) Inventors: NARAE SHIN, Suwon-si (KR); JEONG-KYU HA, Suwon-si (KR)

(21) Appl. No.: 18/909,384

(22) Filed: Oct. 8, 2024

(30) Foreign Application Priority Data
Apr. 22, 2024 (KR) 10-2024-0053591

(51) Int. Cl. H01L 23/495; H01L 21/66; H01L 23/00

(52) U.S. Cl. CPC H01L 23/49541; H01L 22/32; H01L 23/49572; H01L 24/16; H01L 24/32; H01L 24/73; H01L 2224/16227; H01L 2224/32225; H01L 2224/73204

(57) ABSTRACT

Disclosed are semiconductor packages and package modules. The semiconductor package may include a semiconductor chip including an active surface having first to fourth lateral sides, a film substrate including a chip region and an edge region, a first wiring line on the chip and edge regions, and a first bump between the first wiring line and the active surface. The first bump may be adjacent the first lateral side. The first wiring line may include a contact portion in contact with the first bump. The contact portion may include a first and a second portion that is further away than the first portion from the first lateral side. A width of the second portion may be greater than that of the first portion. The first wiring line may vertically overlap the first lateral side and one of the second, third, and fourth lateral sides.

### CROSS-REFERENCE TO RELATED APPLICATION

This U.S. nonprovisional application claims priority under 35 U.S.C § 119 to Korean Patent Application No. 10-2024-0053591, filed on Apr. 22, 2024 in the Korean Intellectual Property Office, the disclosure of which is hereby incorporated by reference in its entirety.

### BACKGROUND

The present inventive concepts relate to a semiconductor package and a package module including the same.

A chip-on-film (COF) package technique has been developed to use a flexible film substrate in order to cope with recent trend toward smaller, thinner, and lighter electronic products. According to the COF package technique, a semiconductor chip may be directly flip-chip bonded to a film substrate and coupled through a short lead to an external circuit. The COF package may be applied to portable terminal devices such as a cellular phone and a personal digital assistant (PDA), laptop computers, or display panels.

### SUMMARY

Some embodiments of the present inventive concepts provide a semiconductor package with improved reliability.

Some embodiments of the present inventive concepts provide a package module with improved reliability.

According to some embodiments of the present inventive concepts, a semiconductor package may include: a semiconductor chip including an active surface, wherein the active surface includes a first lateral side, a second lateral side opposite the first lateral side, a third lateral side, and a fourth lateral side opposite the third lateral side, the first lateral side and the second lateral side being orthogonal to each of the third lateral side and the fourth lateral side; a film substrate including a chip region on which the semiconductor chip is disposed and an edge region surrounding the chip region; a first wiring line on the chip region and the edge region; and a first bump between the first wiring line and the active surface of the semiconductor chip. The first bump may be adjacent the first lateral side. The first wiring line may include a contact portion in contact with the first bump. The contact portion may include: a first portion; and a second portion connected to the first portion and further away than the first portion from the first lateral side. A width of the second portion may be greater than a width of the first portion. The first wiring line may vertically overlap the first lateral side and one of the second, third, and fourth lateral sides.

According to some embodiments of the present inventive concepts, a semiconductor package may include: a film substrate; a semiconductor chip on the film substrate; a first connection pad and a plurality of second connection pads on the film substrate and spaced apart from each other in a first direction parallel to the film substrate; a first wiring line between the film substrate and the semiconductor chip and connected to the first connection pad; a plurality of second wiring lines between the film substrate and the semiconductor chip and connected to the second connection pads; and a first bump between the first wiring line and the semiconductor chip. The first wiring line may include a contact portion in contact with the first bump. The contact portion may be between the second wiring lines. The contact portion may include: a first portion; a variable portion connected to the first portion and having a variable thickness; and a second portion connected to the variable portion and further away than the first portion from the first connection pad. A width of the second portion may be greater than a width of the first portion.

According to some embodiments of the present inventive concepts, a package module may include: a circuit substrate; a display panel spaced apart from the circuit substrate; and a semiconductor package between the circuit substrate and the display panel. The semiconductor package may include: a semiconductor chip; a film substrate including a chip region on which the semiconductor chip is disposed and an edge region surrounding the chip region; a first connection pad and a plurality of second connection pads on the edge region and connected to the display panel; a third connection pad on the edge region; a plurality of fourth connection pads on the edge region and connected to the circuit substrate; a first wiring line between the semiconductor chip and the film substrate and connected to the first connection pad and the third connection pad; a plurality of second wiring lines between the semiconductor chip and the film substrate and connected to the second connection pads; a plurality of third wiring lines between the semiconductor chip and the film substrate and connected to the fourth connection pads; a first bump between the first wiring line and the semiconductor chip; a plurality of second bumps between the second wiring lines and the semiconductor chip; and a plurality of third bumps between the third wiring lines and the semiconductor chip. The first wiring line may include a contact portion in contact with the first bump. The contact portion may include: a first portion; and a second portion connected to the first portion and positioned further away from the first connection pad than is the first portion. A width of the second portion may be greater than a width of the first portion.

### BRIEF DESCRIPTION OF DRAWINGS

FIG. 1A illustrates a plan view showing a semiconductor package according to some embodiments of the present inventive concepts.

FIG. 1B illustrates a cross-sectional view taken along line A-A′ of FIG. 1A.

FIG. 1C illustrates a cross-sectional view taken along line B-B′ of FIG. 1A.

FIG. 2 illustrates an enlarged view showing section A of FIG. 1A.

FIG. 3A illustrates a plan view showing a semiconductor package according to some embodiments of the present inventive concepts.

FIG. 3B illustrates a plan view showing a semiconductor package according to some embodiments of the present inventive concepts.

FIG. 3C illustrates a plan view showing a semiconductor package according to some embodiments of the present inventive concepts.

FIG. 4A illustrates a plan view showing a semiconductor package according to some embodiments of the present inventive concepts.

FIG. 4B illustrates a plan view showing a semiconductor package according to some embodiments of the present inventive concepts.

FIG. 5A illustrates a plan view showing a semiconductor package according to some embodiments of the present inventive concepts.

FIG. 5B illustrates a plan view showing a semiconductor package according to some embodiments of the present inventive concepts.

FIG. 5C illustrates a plan view showing a semiconductor package according to some embodiments of the present inventive concepts.

FIG. 5D illustrates a plan view showing a semiconductor package according to some embodiments of the present inventive concepts.

FIG. 6A illustrates a plan view showing a semiconductor package according to some embodiments of the present inventive concepts.

FIG. 6B illustrates a plan view showing a semiconductor package according to some embodiments of the present inventive concepts.

FIG. 7A illustrates a plan view showing a semiconductor package according to some embodiments of the present inventive concepts.

FIG. 7B illustrates a plan view showing a semiconductor package according to some embodiments of the present inventive concepts.

FIG. 7C illustrates a plan view showing a semiconductor package according to some embodiments of the present inventive concepts.

FIG. 8A illustrates a plan view showing a semiconductor package according to some embodiments of the present inventive concepts.

FIG. 8B illustrates a plan view showing a semiconductor package according to some embodiments of the present inventive concepts.

FIG. 8C illustrates a plan view showing a semiconductor package according to some embodiments of the present inventive concepts.

FIG. 9 illustrates a plan view showing a semiconductor package module according to some embodiments of the present inventive concepts.

### DETAILED DESCRIPTION

Some embodiments of the present inventive concepts will now be described in detail with reference to the accompanying drawings to aid in clearly explaining the present inventive concepts.

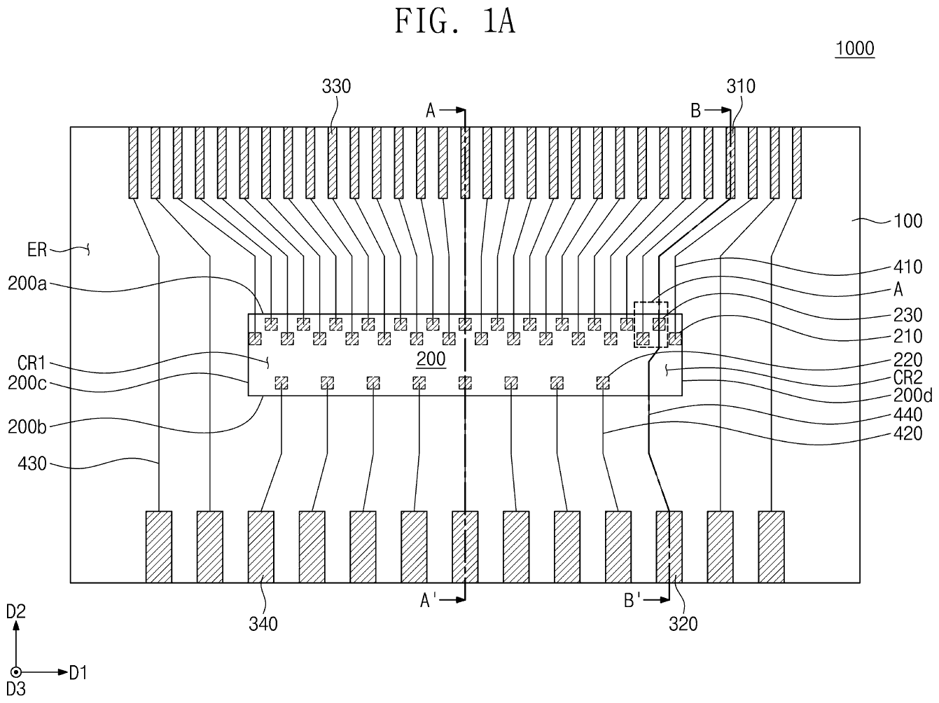

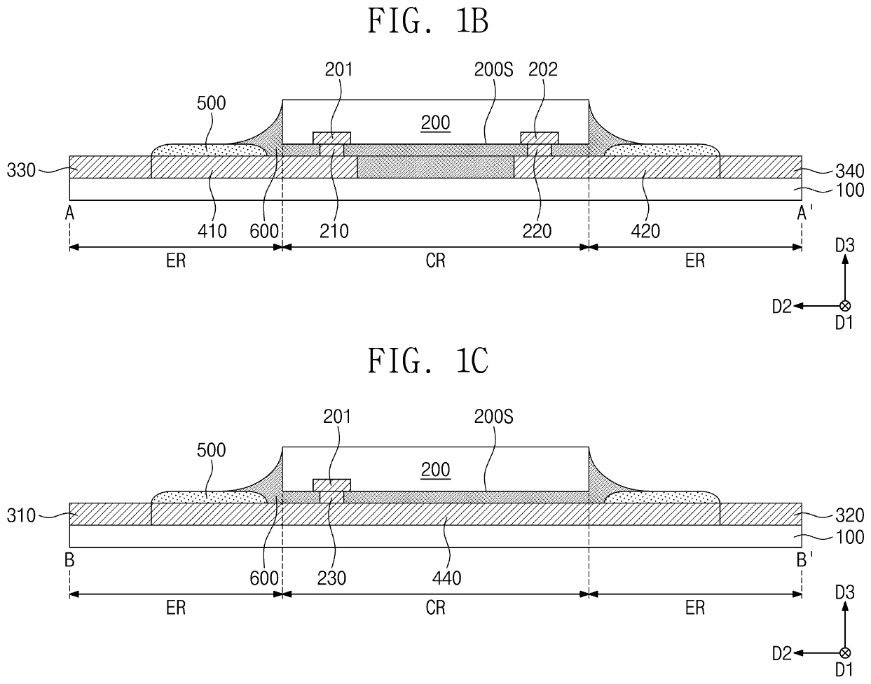

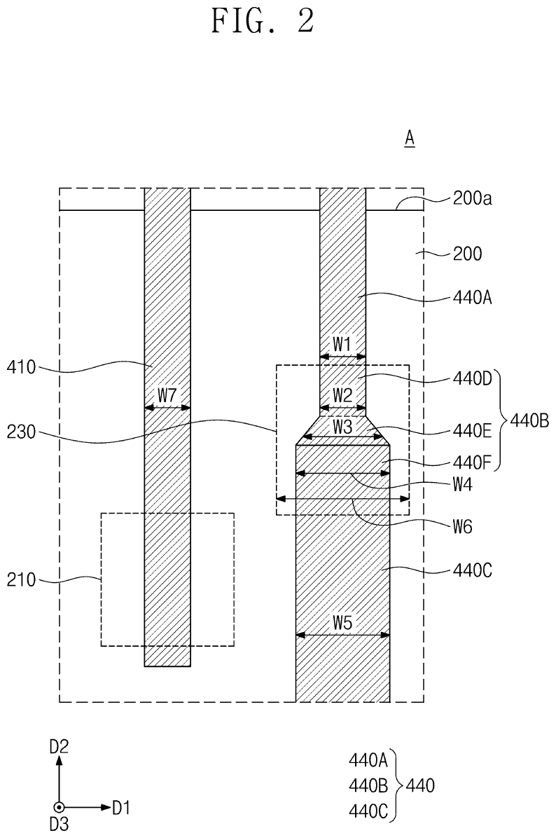

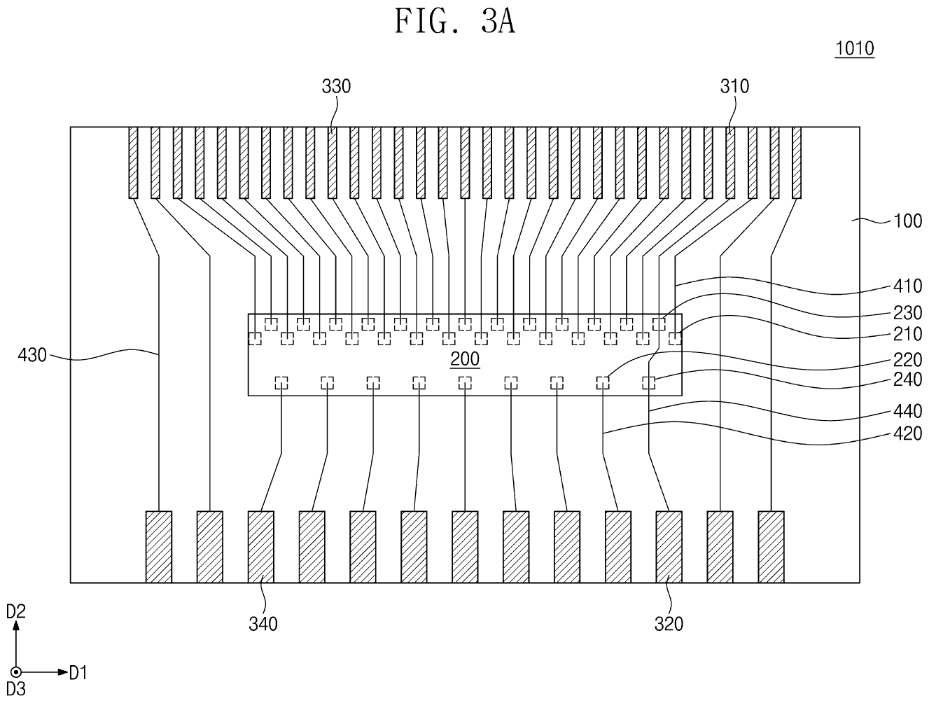

FIG. 1A illustrates a plan view showing a semiconductor package according to some embodiments of the present inventive concepts. FIG. 1B illustrates a cross-sectional view taken along line A-A′ of FIG. 1A. FIG. 1C illustrates a cross-sectional view taken along line B-B′ of FIG. 1A. FIG. 2 illustrates an enlarged view showing section A of FIG. 1A.

Referring to FIGS. 1A and 1B, a semiconductor package 1000 may include a film substrate 100, a semiconductor chip 200, a first connection pad 310, a second connection pad 320, third connection pads 330, fourth connection pads 340, at least one first wiring line 440, second wiring lines 410, third wiring lines 420, a first bump 230, second bumps 210, and third bumps 220.

The film substrate 100 may have a plate shape that extends along a plane elongated in a first direction D1 and a second direction D2. The first direction D1 and the second direction D2 may intersect each other. For example, the first direction D1 and the second direction D2 may be orthogonal to each other. The film substrate 100 may include a polymeric material. For example, the film substrate 100 may include polyimide. The film substrate 100 may be a flexible soft substrate. The film substrate 100 may be bendable.

The film substrate 100 may include a chip region CR on which the semiconductor chip 200 is mounted and an edge region ER which surrounds the chip region CR.

The semiconductor chip 200 may be placed on the chip region CR of the film substrate 100. The semiconductor chip 200 may have a polygonal shape such as a rectangular or square shape when viewed in plan. The semiconductor chip 200 may have a top surface and a bottom surface 200S that are opposite to each other. The bottom surface 200S of the semiconductor chip 200 may be an active surface on which first pads 201 and second pads 202 are disposed which will be discussed below. The semiconductor chip 200 or the bottom surface 200S thereof may have a first lateral side 200a and a second lateral side 200b that extend in the first direction D1 and are spaced apart from each other in the second direction D2, and may also have a third lateral side 200c and a fourth lateral side 200d that extend in the second direction D2 and are spaced apart from each other in the first direction D1.

The semiconductor chip 200 may be a display driver IC that drives a display panel. For example, the semiconductor chip 200 may generate image signals by using data signals transferred from a timing controller, and may output the image signals to the display panel. In some embodiments, the semiconductor chip 200 may be a timing controller connected to the display driver IC.

The semiconductor chip 200 may include first pads 201 disposed on the bottom surface 200S along the first lateral side 200a and second pads 202 disposed on the bottom surface 200S along the second lateral side 200b. For example, the first pads 201 may be output pads, and the second pads 202 may be input pads. The first pads 201 may contact and (vertically) overlap the first bumps 230 and/or the second bumps 210 in a third direction D3 perpendicular to a top surface of the film substrate 100. The second pads 202 may contact and (vertically) overlap in the third direction D3 with the third bumps 220.

The film substrate 100 may be provided on its edge region ER with the first connection pad 310, the second connection pad 320, the third connection pads 330, and the fourth connection pads 340. The first connection pad 310 and the third connection pads 330 may be disposed spaced apart from each other in the first direction D1. The fourth connection pads 340 may be disposed spaced apart from each other in the first direction D1. When viewed in plan, the third connection pads 330 and the second connection pads 320 may be disposed spaced apart in the second direction D2 from each other across the semiconductor chip 200 (e.g., the third connection pads 330 and the second connection pads 320 may be on opposite sides of the semiconductor chip 200). When viewed in plan, the first bump 230 and/or the second bumps 210 (or the first pads 201) may be interposed between the third connection pads 330 and the third bumps 220 (or the second pads 202). When viewed in plan, the third bumps 220 (or the second pads 202) may be interposed between the fourth connection pads 340 and the first bump 230 and/or between the fourth connection pads 340 and the second bumps 210 (or the first pads 201).

The second connection pad 320 may be disposed spaced apart in the first direction D1 from the fourth connection pads 340. The first connection pad 310 and the third connection pads 330 may be output pads, and the second connection pad 320 and the fourth connection pads 340 may be input pads.

A width in the first direction D1 of the output pads 310 and 330 may be less than a width in the first direction D1 of the input pads 320 and 340. The number of the third connection pads 330 may be greater than the number of the fourth connection pads 340.

The first, second, third, and fourth connection pads 310, 320, 330, and 340 may include a conductive material. For example, the first, second, third, and fourth connection pads 310, 320, 330, and 340 may include copper (Cu).

The first wiring line 440 may be connected to the first connection pad 310 and the second connection pad 320. The first wiring line 440 may be disposed on the chip region CR and the edge region ER. The first wiring line 440 may have opposite ends disposed on the edge region ER. The first wiring line 440 may vertically overlap two different sides of the bottom surface 200S of the semiconductor chip 200. For example, the first wiring line 440 may vertically overlap the first lateral side 200a and the second lateral side 200b.

The second wiring lines 410 may be correspondingly connected to the third connection pads 330. The second wiring lines 410 may be disposed on the chip region CR and the edge region ER. One end of each of the second wiring lines 410 may be disposed on the edge region ER, and another end of each of the second wiring lines 410 may be disposed on the chip region CR. The second wiring lines 410 may not be connected to the second connection pad 320 and/or the fourth connection pads 340. The second wiring lines 410 may vertically overlap the first lateral side 200a, and may not vertically overlap the second lateral side 200b.

The third wiring lines 420 may be correspondingly connected to the fourth connection pads 340. The third wiring lines 420 may be disposed on the chip region CR and the edge region ER. One end of each of the third wiring lines 420 may be disposed on the edge region ER, and another end of each of the third wiring lines 420 may be disposed on the chip region CR. The third wiring lines 420 may not be connected to the first connection pad 310 and/or the third connection pads 330. The third wiring lines 420 may vertically overlap the second lateral side 200b, and may not vertically overlap the first lateral side 200a.

The second wiring lines 410 may be spaced apart from each other in the first direction D1, and may extend in the second direction D2 from corresponding third connection pads 330. The third wiring lines 420 may be spaced apart from each other in the first direction D1, and may extend in the second direction D2 from corresponding fourth connection pads 340. The second wiring lines 410 may be spaced apart in the second direction D2 from the third wiring lines 420.

The first wiring line 440 may be disposed spaced apart in the first direction D1 from the second wiring lines 410. The first wiring line 440 may be disposed spaced apart in the first direction D1 from the third wiring lines 420. The first wiring line 440 may be disposed between the second wiring lines 410 that neighbor along the first direction D1.

The fourth wiring lines 430 may be connected to one or more output pads that are not connected to any of the first wiring line 440 and the second wiring lines 410, and connected to one or more input pads that are not connected to any of the first wiring line 440 and the third wiring lines 420. The fourth wiring lines 430 may be disposed only on the edge region ER. The fourth wiring lines 430 may extend in the second direction D2 and may be spaced apart from each other in the first direction D1.

Although not shown, the semiconductor package 1000 may further include dummy wiring lines disposed on the film substrate 100. The dummy wiring lines may be connected to none of the first connection pads 310 and the second connection pads 320. The dummy wiring lines may be spaced apart in the first direction D1 from the wiring lines 410, 420, 430, and 440, and may extend in the second direction D2.

The wiring lines 410, 420, 430, and 440 and the dummy wiring lines may include a conductive material. For example, the wiring lines 410, 420, 430, and 440 and the dummy wiring lines may include copper (Cu).

Each of the second wiring lines 410 may have a width of about 6 to 9 μm or about 7 to 8 μm. Each of the third wiring lines 420 may have a width of about 15 to 40 μm or about 20 to 30 μm. The width of the third wiring line 420 may be greater than the width of the second wiring line 410. The number of the second wiring lines 410 may be greater than the number of the third wiring lines 420.

As the first wiring line 440 extends in the second direction D2 on the chip region CR, the chip region CR may be divided into a first chip region CR1 and a second chip region CR2 that are defined based on the first wiring line 440. As shown in FIG. 1A, when viewed in plan, the first chip region CR1 may be defined to refer to the chip region CR disposed on one side of the first wiring line 440 and the second chip region CR2 may be defined to refer to the chip region CR disposed on another side (or the opposite side) of the first wiring line 440. The second wiring lines 410 may be disposed on both of the first chip region CR1 and the second chip region CR2. For example, the first wiring line 440 may be disposed between the second wiring lines 410. The third wiring lines 420 may be disposed only on the first chip region CR1, and may not be disposed on the second chip region CR2.

The first bump 230 may be in contact with the first wiring line 440, and the first wiring line 440 may include a contact portion 440B in contact with the first bump 230. The first bump 230 may be disposed between the contact portion 440B and one of the first pads 201. The contact portion 440B will be further discussed in detail below. The first bump 230 may vertically overlap the one of the first pads 201.

The second bumps 210 may be correspondingly in contact with the second wiring lines 410. The second bumps 210 may be interposed between the second wiring lines 410 and portions of the first pads 201. The second bumps 210 may correspondingly vertically overlap the portions of the first pads 201.

The third bumps 220 may be correspondingly in contact with the third wiring lines 420. The third bumps 220 may be interposed between the second pads 202 and the third wiring lines 420. The third bumps 220 may correspondingly vertically overlap the second pads 202.

The number of the second bumps 210 may be greater than the number of the third bumps 220. The first bump 230 and the second bumps 210 may be spaced apart from each other in the first direction D1, and may be respectively disposed on the first wiring line 440 and the second wiring lines 410. The second bumps 210 and the third bumps 220 may be spaced apart from each other in the second direction D2, and may be respectively disposed on the second wiring lines 410 and the third wiring lines 420.

The first, second, and third bumps 230, 210, 220 may include a conductive material. For example, the first, second, and third bumps 230, 210, 220 may include copper (Cu).

Referring still to FIGS. 1A and 1B, the semiconductor package 1000 may further include a wiring protection layer 500 and an underfill layer 600.

The wiring protection layer 500 may be disposed on the film substrate 100 to cover or be on the first wiring line 440, the second wiring lines 410, and the third wiring lines 420. The wiring protection layer 500 may expose the first connection pad 310, the second connection pad 320, the third connection pads 330, and the fourth connection pads 340. The wiring protection layer 500 may include a dielectric material. For example, the wiring protection layer 500 may include a solder resist material.

The underfill layer 600 may be disposed between the bottom surface 200S of the semiconductor chip 200 and the top surface of the film substrate 100. For example, the underfill layer 600 may cover a lateral or side surface of the semiconductor chip 200, a portion of a top surface of the wiring protection layer 500, lateral or side surfaces of the second bumps 210 and the third bumps 220, portions of top and lateral or side surfaces of the second wiring lines 410 and the third wiring lines 420, and a portion of the top surface of the film substrate 100. The underfill layer 600 may include a dielectric material. For example, the underfill layer 600 may include an epoxy-based polymer.

As shown in FIG. 1C, the underfill layer 600 may cover a lateral or side surface of the first bump 230 and portions of top and lateral or side surfaces of the first wiring line 440.

Referring to FIGS. 1A and 2, the first wiring line 440 may include a first line portion 440A, a contact portion 440B, and a second line portion 440C. The first line portion 440A may connect the first connection pad 310 and the first bump 230 to each other. The second line portion 440C may connect the second connection pad 320 and the first bump 230 to each other. The contact portion 440B may be in contact with the first bump 230.

A width W1 of the first line portion 440A may be the same as a width W7 of the second wiring line 410. For example, the width W1 of the first line portion 440A may range from about 6 to 9 μm or from about 7 to 8 μm.

The contact portion 440B may include a first contact portion 440D, a variable (width) portion 440E, and a second contact portion 440F. The first contact portion 440D may be connected to the first line portion 440A, and the second contact portion 440F may be connected to the second line portion 440C. The variable portion 440E may be a part whose width W3 is changed on the contact portion 440B, and may connect the first contact portion 440D and the second contact portion 440F to each other.

A width W2 of the first contact portion 440D may be the same as the width W1 of the first line portion 440A. For example, the width W2 of the first contact portion 440D may range from about 6 to 9 μm or from about 7 to 8 μm.

A width W4 of the second contact portion 440F may be greater than the width W2 of the first contact portion 440D. For example, the width W4 of the second contact portion 440F may range from about 8 to 11 μm or from about 9 to 10 μm.

The width W3 of the variable portion 440E may gradually increase in a direction from the first contact portion 440D to the second contact portion 440F. For example, the width W3 of the variable portion 440E may become greater from about 6 to 9 μm to about 8 to 11 μm, or from about 7 to 8 μm to about 9 to 10 μm, in a direction from the first contact portion 440D to the second contact portion 440F.

The width W4 of the second contact portion 440F may be less than a width W6 of the first bump 230. For example, the width W6 of the first bump 230 may range from about 10 to 25 μm or from about 14 to 21 μm.

A width W5 of the second line portion 440C may be the same as or greater than the width W4 of the second contact portion 440F. The width W5 of the second line portion 440C may become wider at least one time in a direction from the first bump 230 to the second connection pad 320. For example, the width W5 of the second line portion 440C may become greater from about 8 to 11 μm to about 20 to 30 μm in a direction from the first bump 230 to the second connection pad 320.

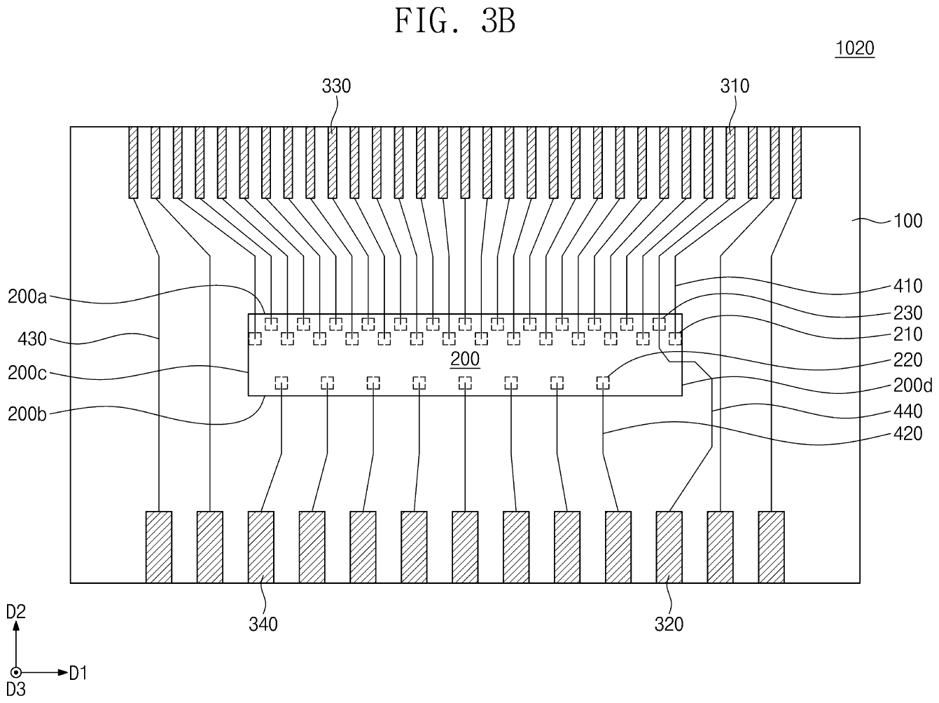

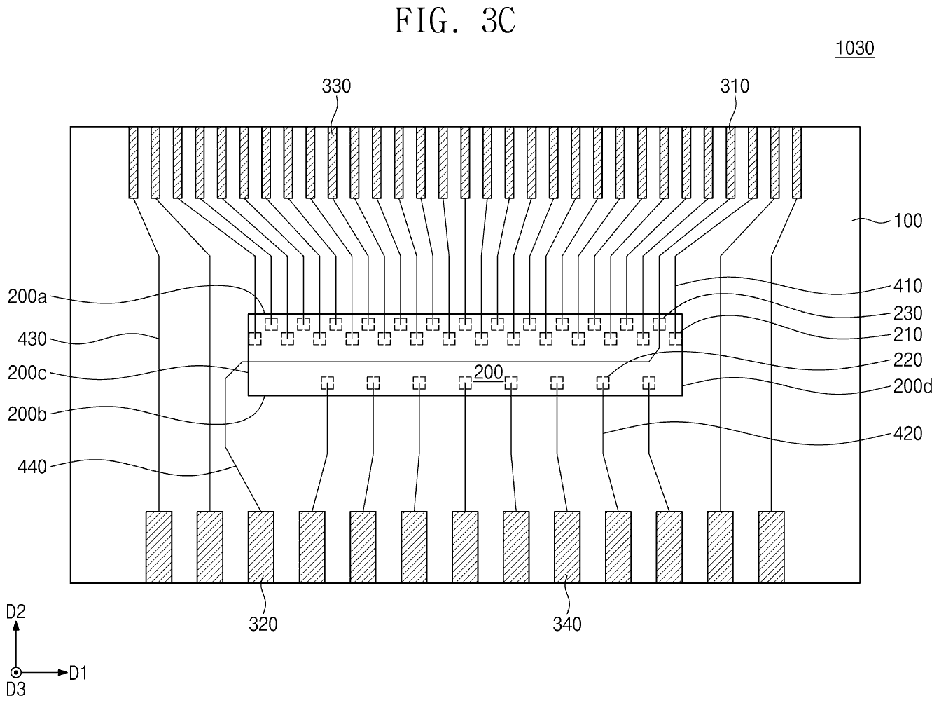

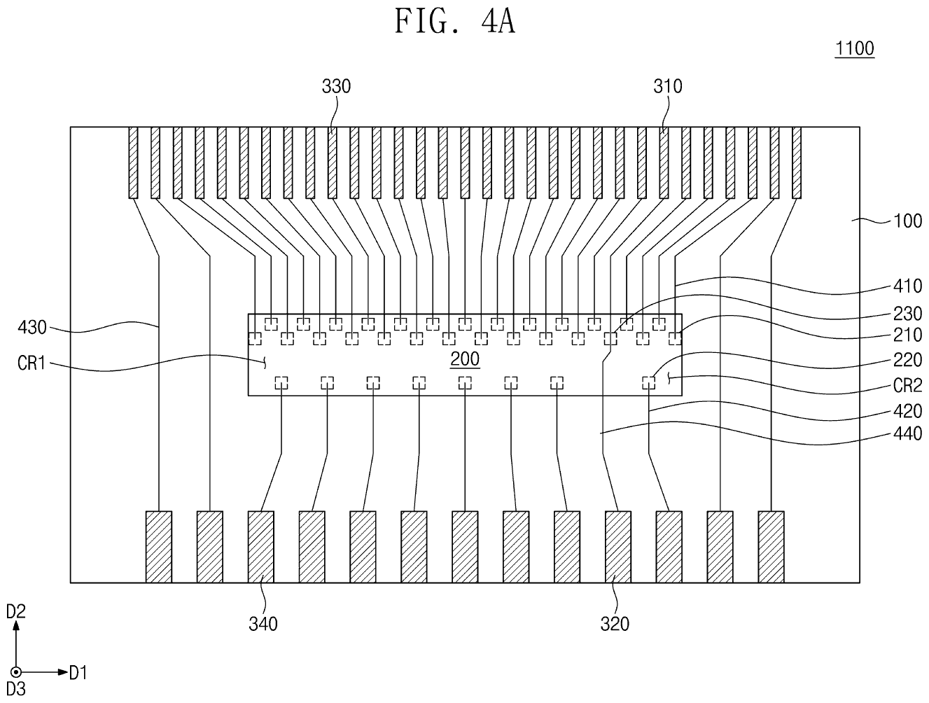

FIG. 3A illustrates a plan view showing a semiconductor package according to some embodiments of the present inventive concepts.

Referring to FIG. 3A, a semiconductor package 1010 may further include a fourth bump 240 between the first wiring line 440 and the semiconductor chip 200. The fourth bump 240 may be in contact with the first wiring line 440. The fourth bump 240 may be interposed between the first wiring line 440 and one of the second pads 202. The fourth bump 240 may vertically overlap the one of the second pads 202.

The fourth bump 240 may be spaced apart in the first direction D1 from the third bumps 230, and may be disposed on the first wiring line 440. The fourth bump 240 may include a conductive material. For example, the fourth bump 240 may include copper (Cu).

FIG. 3B illustrates a plan view showing a semiconductor package according to some embodiments of the present inventive concepts. Referring to FIG. 3B, in a semiconductor package 1020, the first wiring line 440 may vertically overlap the first lateral side 200a and the fourth lateral side 200d.

FIG. 3C illustrates a plan view showing a semiconductor package according to some embodiments of the present inventive concepts. Referring to FIG. 3C, in a semiconductor package 1030, the first wiring line 440 may vertically overlap the first lateral side 200a and the third lateral side 200c. The third lateral side 200c may be further away than the fourth lateral side 200d from the first bump 230.

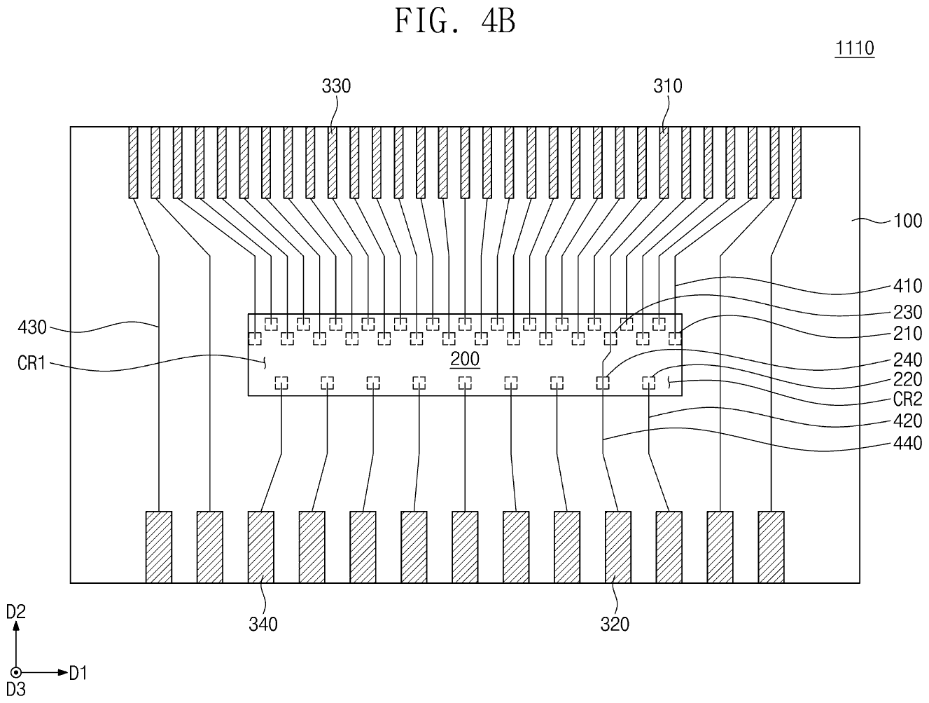

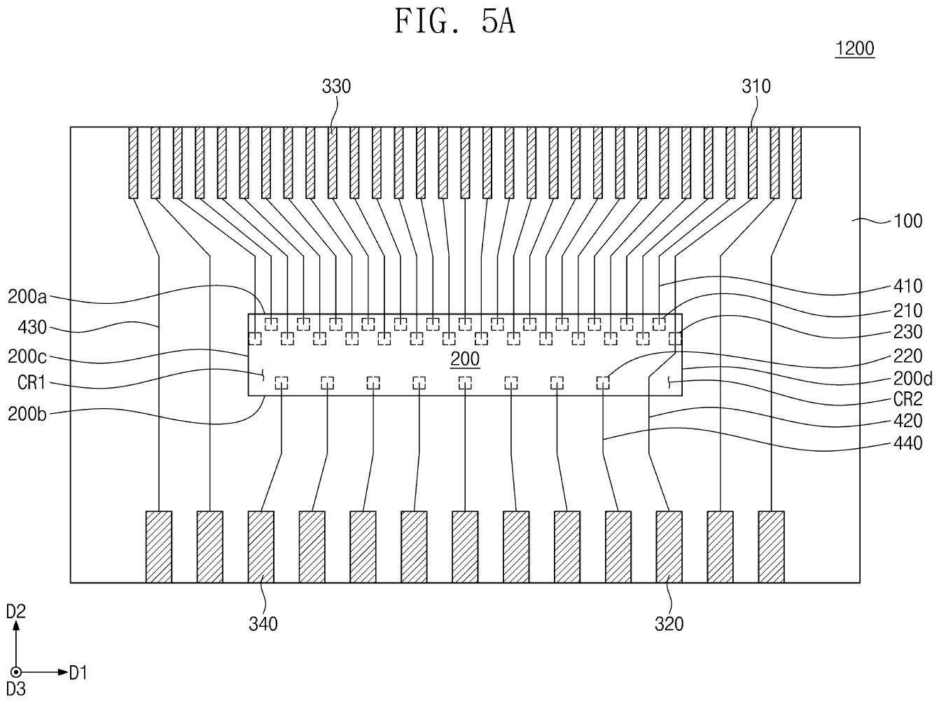

FIG. 4A illustrates a plan view showing a semiconductor package according to some embodiments of the present inventive concepts. FIG. 4B illustrates a plan view showing a semiconductor package according to some embodiments of the present inventive concepts.

Referring to FIGS. 4A and 4B, in semiconductor packages 1100 and 1110, the second wiring lines 410 may be disposed on both of the first chip region CR1 and the second chip region CR2. For example, the first wiring line 440 may be disposed between the second wiring lines 410. The third wiring lines 420 may be disposed on both of the first chip region CR1 and the second chip region CR2. For example, the first wiring line 440 may be disposed between the third wiring lines 420.

Referring to FIG. 4B, the semiconductor package 1110 may further include a fourth bump 240 between the first wiring line 440 and the semiconductor chip 200. A description of the fourth bump 240 of the semiconductor package 1110 may be the same as that of the fourth bump 240 of the semiconductor package 1010 depicted in FIG. 3A.

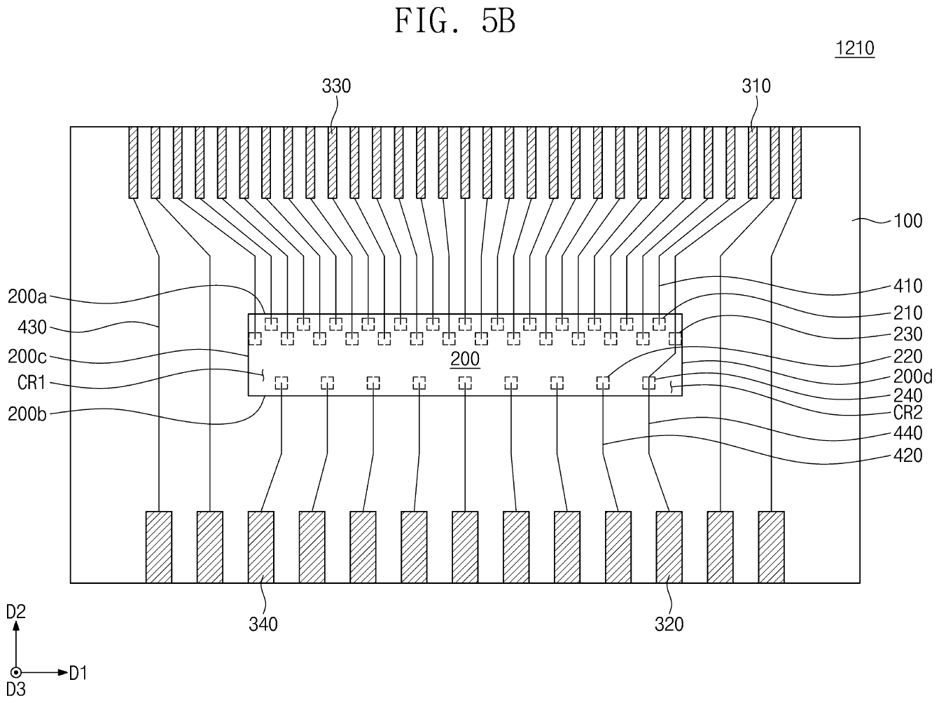

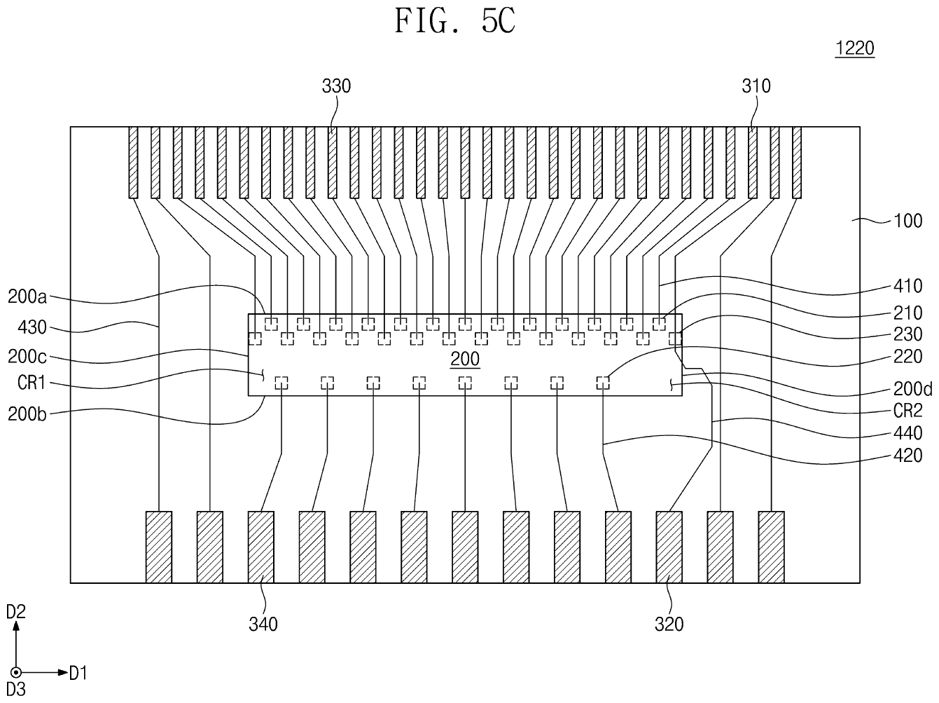

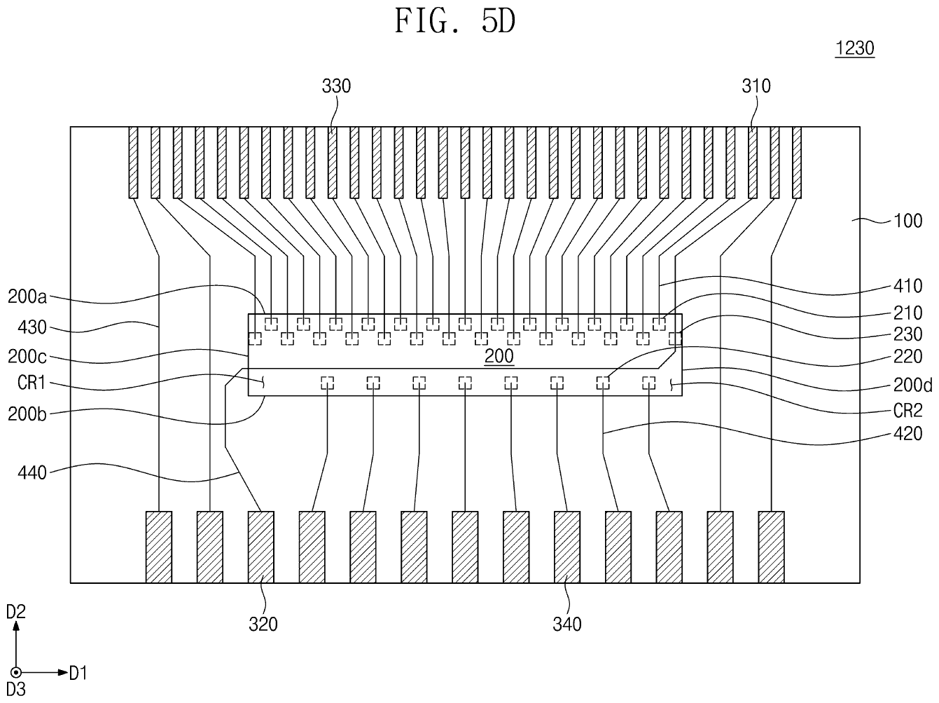

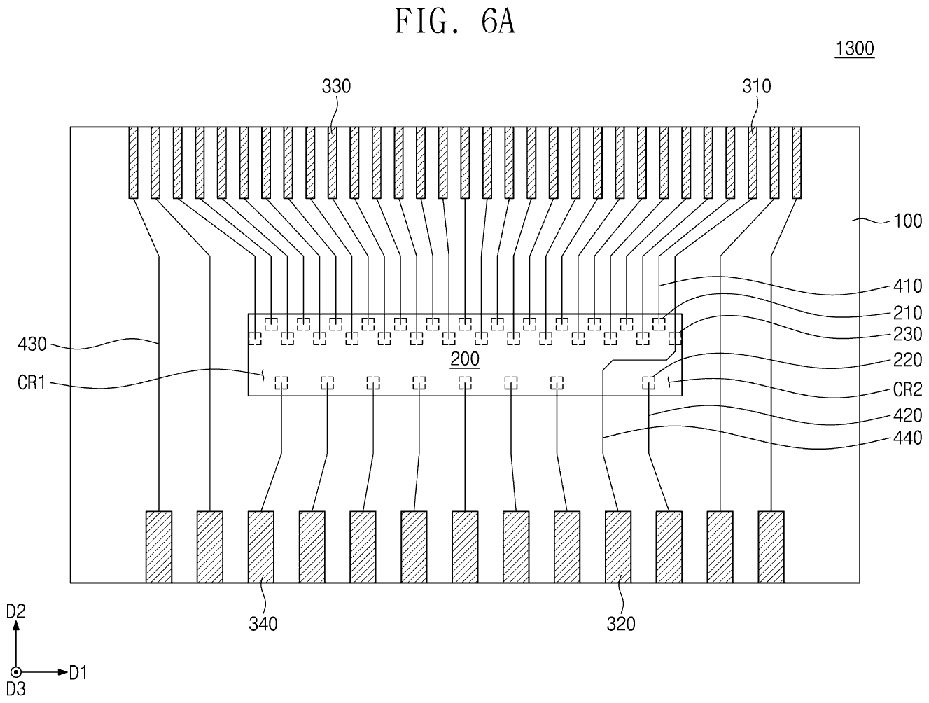

FIG. 5A illustrates a plan view showing a semiconductor package according to some embodiments of the present inventive concepts. FIG. 5B illustrates a plan view showing a semiconductor package according to some embodiments of the present inventive concepts. FIG. 5C illustrates a plan view showing a semiconductor package according to some embodiments of the present inventive concepts. FIG. 5D illustrates a plan view showing a semiconductor package according to some embodiments of the present inventive concepts.

Referring to FIGS. 5A, 5B, 5C, and 5D, in semiconductor packages 1200, 1210, 1220, and 1230, the second wiring lines 410 may be disposed only on the first chip region CR1, and may not be disposed on the second chip region CR2. The third wiring lines 420 may be disposed only on the first chip region CR1, and may not be disposed on the second chip region CR2.

Referring to FIGS. 5A and 5B, in semiconductor packages 1200 and 1210, the first wiring line 440 may vertically overlap the first lateral side 200a and the second lateral side 200b.

Referring to FIG. 5B, the semiconductor package 1210 may further include a fourth bump 240 between the first wiring line 440 and the semiconductor chip 200. A description of the fourth bump 240 of the semiconductor package 1210 may be the same as that of the fourth bump 240 of the semiconductor package 1010 depicted in FIG. 3A.

Referring to FIG. 5C, in a semiconductor package 1220, the first wiring line 440 may vertically overlap the first lateral side 200a and the fourth lateral side 200d.

Referring to FIG. 5D, in a semiconductor package 1230, the first wiring line 440 may vertically overlap the first lateral side 200a and the third lateral side 200c.

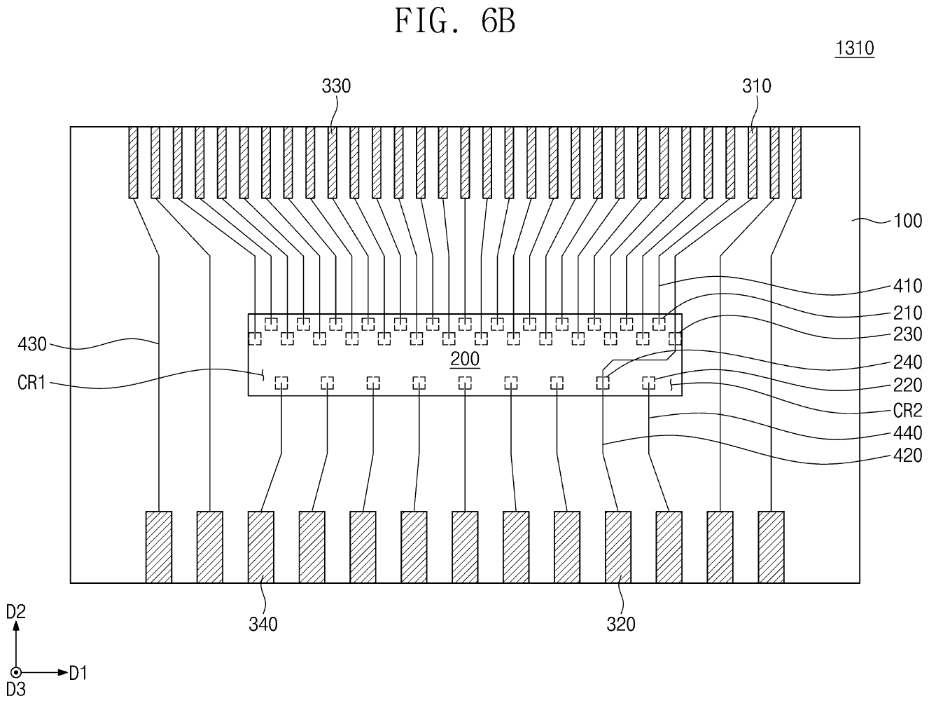

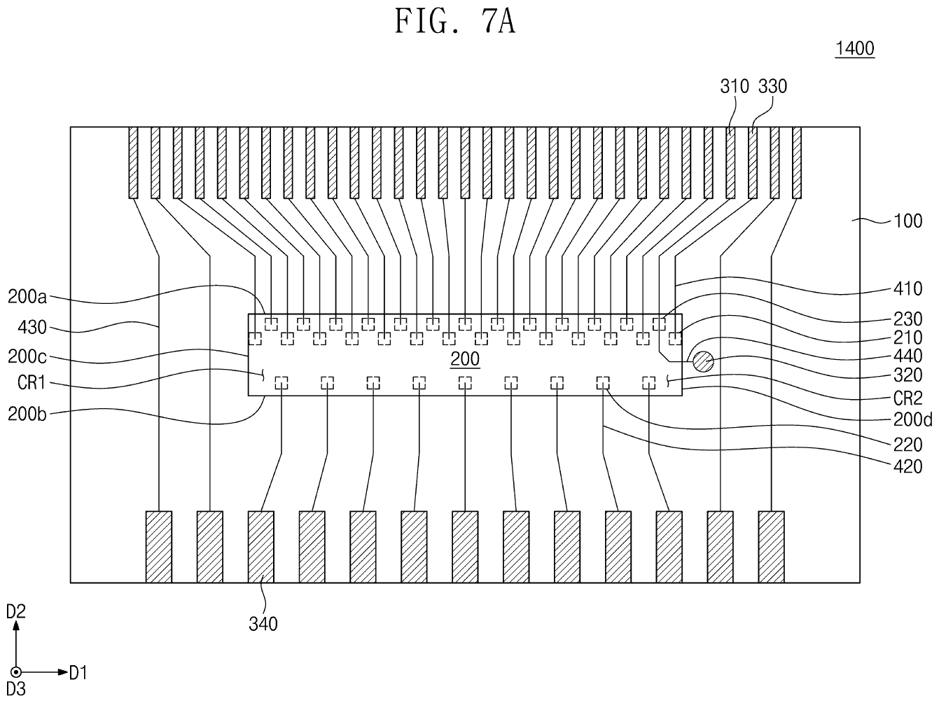

FIG. 6A illustrates a plan view showing a semiconductor package according to some embodiments of the present inventive concepts. FIG. 6B illustrates a plan view showing a semiconductor package according to some embodiments of the present inventive concepts.

Referring to FIGS. 6A and 6B, in semiconductor packages 1300 and 1310, the second wiring lines 410 may be disposed only on the first chip region CR1, and may not be disposed on the second chip region CR2. In the semiconductor packages 1300 and 1310, the third wiring lines 420 may be disposed on both of the first chip region CR1 and the second chip region CR2. For example, the first wiring line 440 may be disposed between the third wiring lines 420.

Referring to FIG. 6B, the semiconductor package 1310 may further include a fourth bump 240 between the first wiring line 440 and the semiconductor chip 200. A description of the fourth bump 240 of the semiconductor package 1310 may be the same as that of the fourth bump 240 of the semiconductor package 1010 depicted in FIG. 3A.

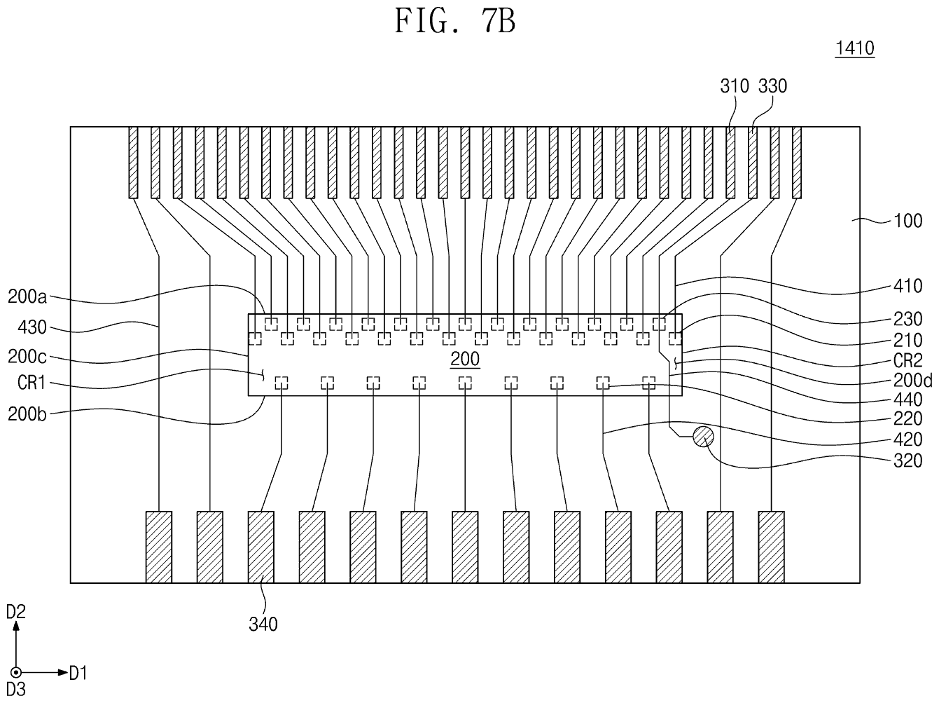

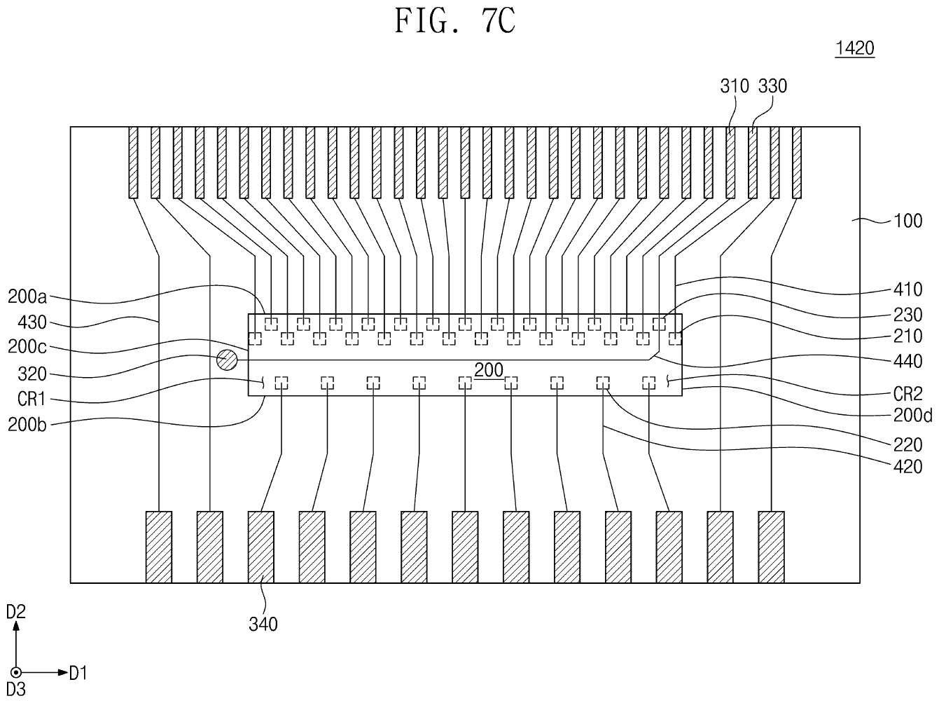

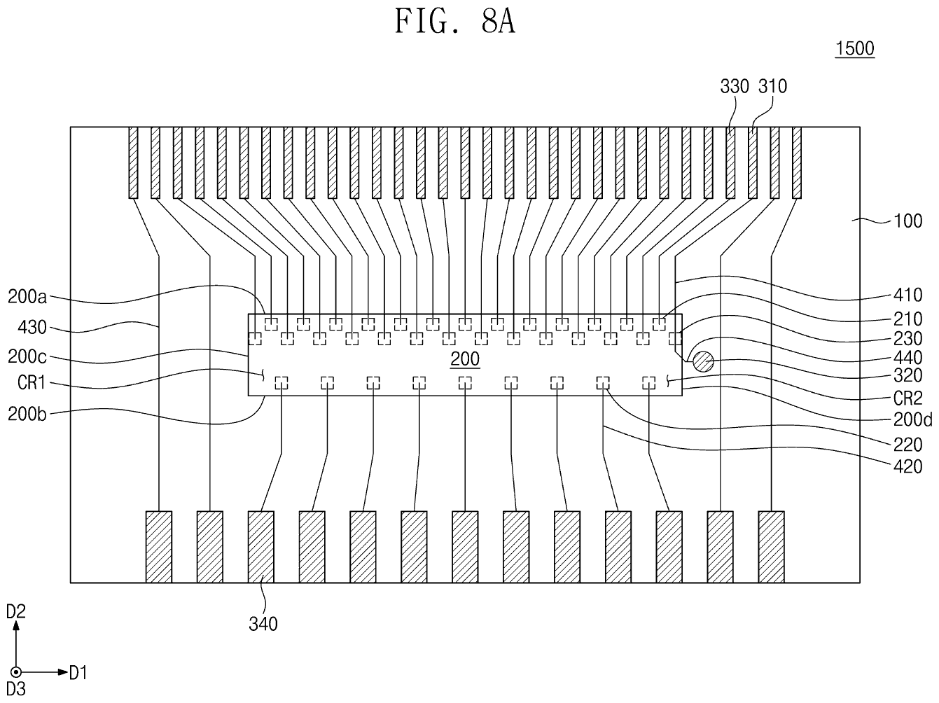

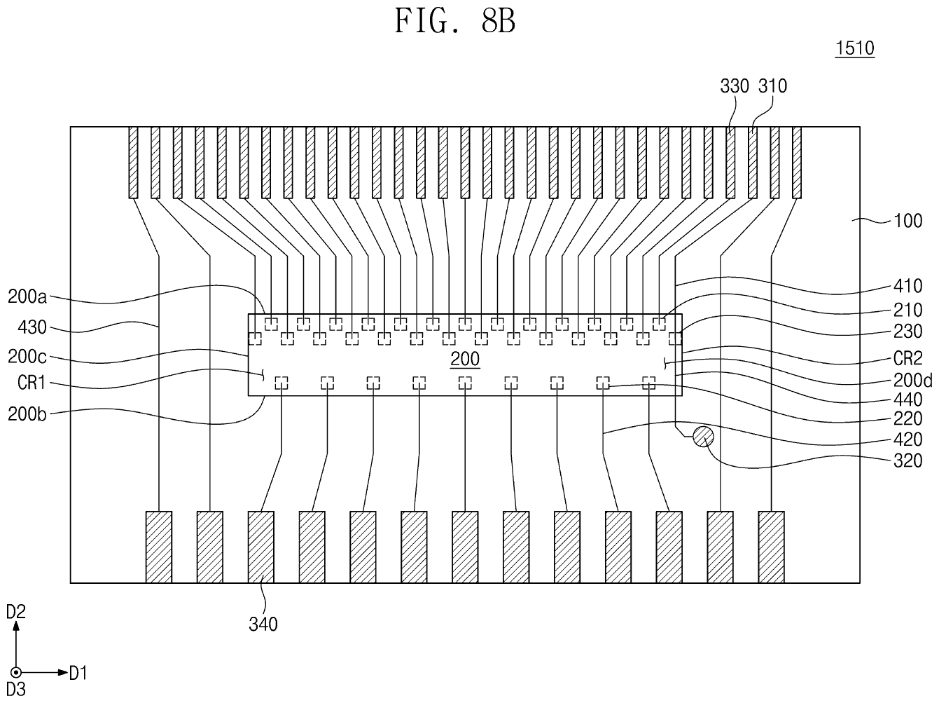

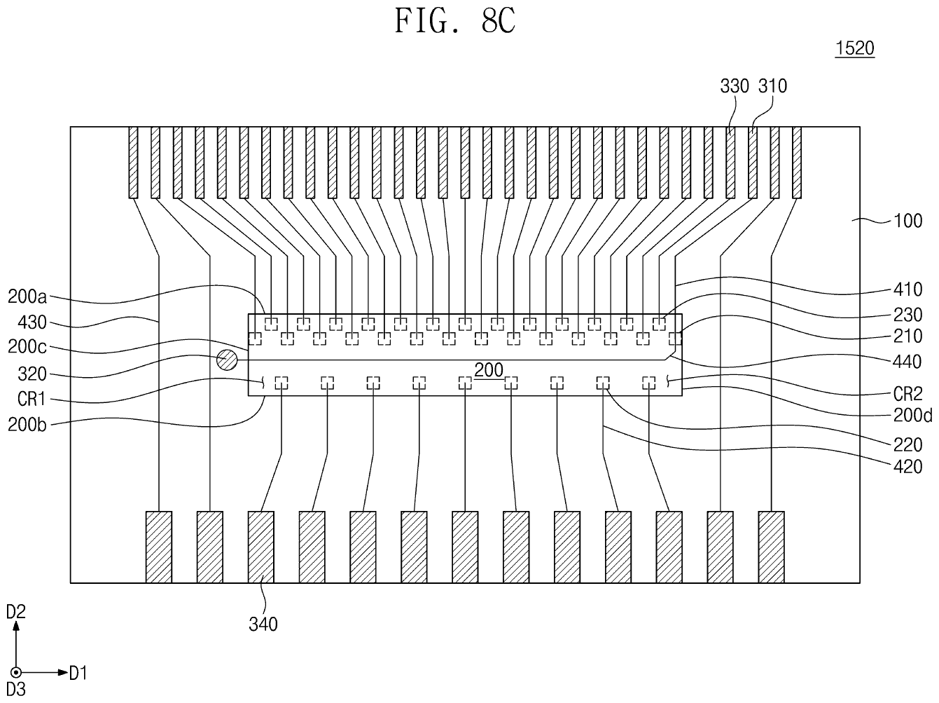

FIG. 7A illustrates a plan view showing a semiconductor package according to some embodiments of the present inventive concepts. FIG. 7B illustrates a plan view showing a semiconductor package according to some embodiments of the present inventive concepts. FIG. 7C illustrates a plan view showing a semiconductor package according to some embodiments of the present inventive concepts. FIG. 8A illustrates a plan view showing a semiconductor package according to some embodiments of the present inventive concepts. FIG. 8B illustrates a plan view showing a semiconductor package according to some embodiments of the present inventive concepts. FIG. 8C illustrates a plan view showing a semiconductor package according to some embodiments of the present inventive concepts.

Referring to FIGS. 7A, 7B, 7C, 8A, 8B, and 8C, in semiconductor packages 1400, 1410, 1420, 1500, 1510, and 1520, the second connection pad 320 may be disposed spaced apart in the second direction D2 from the fourth connection pads 340. The first connection pad 310 and the third connection pads 330 may be output pads, the second connection pad 320 may be a test pad, and the fourth connection pads 340 may be input pads.

Referring to FIGS. 7A, 7B, and 7C, in the semiconductor packages 1400, 1410, and 1420, the second wiring lines 410 may be disposed on both of the first chip region CR1 and the second chip region CR2. For example, the first wiring line 440 may be disposed between the second wiring lines 410.

Referring to FIG. 7A, the first wiring line 440 of the semiconductor package 1400 may vertically overlap the first lateral side 200a and the fourth lateral side 200d.

Referring to FIG. 7B, the first wiring line 440 of the semiconductor package 1410 may vertically overlap the first lateral side 200a and the second lateral side 200b.

Referring to FIG. 7C, the first wiring line 440 of the semiconductor package 1420 may vertically overlap the first lateral side 200a and the third lateral side 200c.

Referring to FIGS. 8A, 8B, and 8C, in the semiconductor packages 1500, 1510, and 1520, the second wiring lines 410 may be disposed only on the first chip region CR1, and may not be disposed on the second chip region CR2.

Referring to FIG. 8A, the first wiring line 440 of the semiconductor package 1500 may vertically overlap the first lateral side 200a and the fourth lateral side 200d.

Referring to FIG. 8B, the first wiring line 440 of the semiconductor package 1510 may vertically overlap the first lateral side 200a and the second lateral side 200b.

Referring to FIG. 8C, the first wiring line 440 of the semiconductor package 1520 may vertically overlap the first lateral side 200a and the third lateral side 200c.

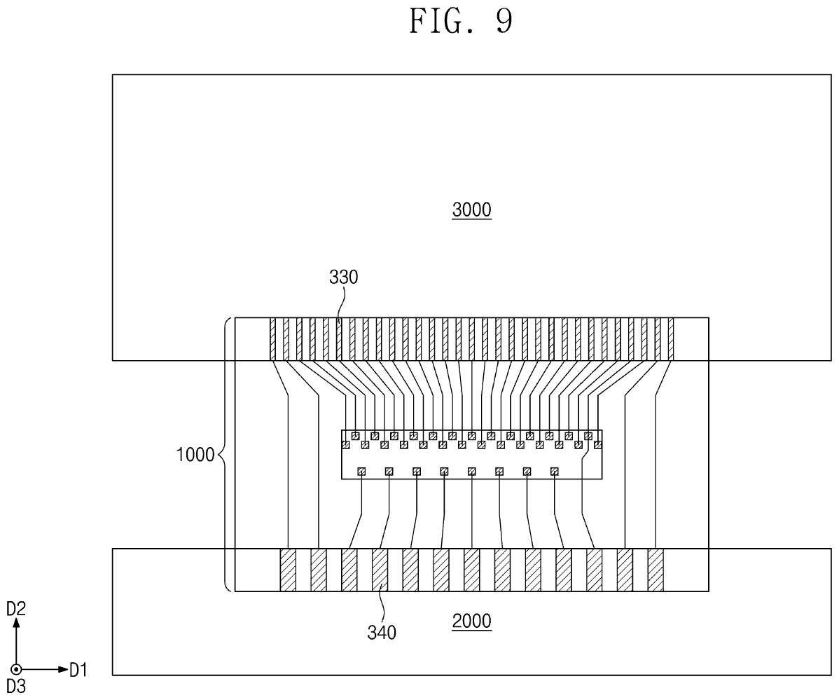

FIG. 9 illustrates a plan view showing a semiconductor package module according to some embodiments of the present inventive concepts.

Referring to FIG. 9, a semiconductor package module may include a semiconductor package 1000, a circuit substrate 2000, and a display panel 3000.

Although the semiconductor package 1000 of FIG. 1A is illustrated as the semiconductor package 1000 of the semiconductor package module, the semiconductor package 1000 of FIG. 1A may be replaced with other semiconductor packages according to some embodiments of the present inventive concepts. Only one semiconductor package 1000 is illustrated in FIG. 9, but there may be no limitation on the number of the semiconductor package(s) 1000.

The circuit substrate 2000 may be disposed on the first top surface of the film substrate 100 of the semiconductor package 1000. The circuit substrate 2000 may be adjacent to one side of the film substrate 100. The circuit substrate 2000 may be, for example, a printed circuit board (PCB) or a flexible printed circuit board (FPCB). An input connection section (not shown) may be interposed between and connect to each other the input pads 340 and the circuit substrate 2000. The circuit substrate 2000 may be electrically connected to the semiconductor chip 200 through the input pads 340 and the third wiring lines 420.

The display panel 3000 may be disposed on the top surface of the film substrate 100 of the semiconductor package 1000. The display panel 3000 may be adjacent to another side of the film substrate 100. An output connection section (not shown) may be interposed between and connect the output pads 310 and 330 and the display panel 3000. The display panel 3000 may be electrically connected to the semiconductor chip 200 through the output pads 310 and 330 and the second wiring lines 410.

The semiconductor chip 200 may be supplied with signals from the circuit substrate 2000 through the input pads 340 and the third wiring lines 420. The semiconductor chip 200 may include driving integrated circuits (e.g., gate driving integrated circuit and/or data driving integrated circuit), and may generate driving signals (e.g., gate driving signal and/or data driving signal). The driving signal generated from the semiconductor chip 200 may be supplied through the input pads 310 and 330 and the second wiring lines 410 to a gate line and/or a data line of the display panel 3000. Therefore, the display panel 3000 may operate.

The first wiring line 440 according to the present inventive concepts may be a wiring line of a semiconductor package, may connect an input pad and an output pad to each other, and may be connected to a semiconductor chip 200. Therefore, there may occur an effect of reduction in electrical pathway.

In the first wiring line 440, a width of a portion connected to the first connection pad 310 may be different from that of a portion connection to the second connection pad 320. The width of the portion connected to the second connection pad 320 may be greater than the width of the portion connected to the first connection pad 310.

In a semiconductor package according to the present inventive concepts, a width of the first wiring line 440 may increase at a contact portion in contact with the first bump 230. Thus, a top surface of the first wiring line 440 in contact with the first bump 230 may have a surface area that increases less compared to a case where a width of the first wiring line 440 does not increase, thereby preventing separation between the first wiring line 440 and the first bump 230. In addition, as a width of the first wiring line 440 increases on the contact portion, the first wiring line 440 may be prevented from crack or fracture. As a result, the semiconductor package may increase in reliability.

A semiconductor package according to the present inventive concepts may include a wiring line which directly connects a circuit board and a display panel and which is connected to a semiconductor chip, and may also include a bump interposed between the wiring line and the semiconductor chip. A width of the wiring line may be changed at a contact portion in contact with the bump, and thus it may be possible to prevent issues of line disconnection and contact failure between the wiring line and the bump. In conclusion, there may be an increase in reliability of the wiring line and the semiconductor package.

Although the present inventive concepts have been described in connection with the example embodiments of the present inventive concepts illustrated in the accompanying drawings, it will be understood by one of ordinary skill in the art that variations in form and detail may be made therein without departing from the scope of the present inventive concepts. The above disclosed example embodiments should thus be considered illustrative and not restrictive.

What is claimed is:

1. A semiconductor package, comprising:
a semiconductor chip including an active surface, wherein the active surface includes a first lateral side, a second lateral side opposite the first lateral side, a third lateral side, and a fourth lateral side opposite the third lateral side, the first lateral side and the second lateral side being orthogonal to each of the third lateral side and the fourth lateral side;
a film substrate including a chip region on which the semiconductor chip is disposed and an edge region surrounding the chip region;
a first wiring line on the chip region and the edge region; and
a first bump between the first wiring line and the active surface of the semiconductor chip,
wherein the first bump is adjacent the first lateral side,
wherein the first wiring line includes a contact portion in contact with the first bump,
wherein the contact portion includes:
a first portion; and
a second portion connected to the first portion and further away than the first portion from the first lateral side,
wherein a width of the second portion is greater than a width of the first portion, and
wherein the first wiring line vertically overlaps the first lateral side and one of the second, third, and fourth lateral sides.

2. The semiconductor package of claim 1, wherein the width of the second portion is less than a width of the first bump.

3. The semiconductor package of claim 1, further comprising a first connection pad, a second connection pad, a plurality of third connection pads, and a plurality of fourth connection pads on the edge region,
wherein the first connection pad and the third connection pads are spaced apart from each other in a first direction parallel to a top surface of the film substrate,
wherein the fourth connection pads are spaced apart from each other in the first direction,
wherein the third connection pads and the fourth connection pads are spaced apart from each other across the semiconductor chip, and
wherein the first wiring line connects the first connection pad, the first bump, and the second connection pad to each other.

4. The semiconductor package of claim 3, wherein the number of the third connection pads is greater than the number of the fourth connection pads.

5. The semiconductor package of claim 3, wherein the second connection pad is spaced apart in the first direction from the fourth connection pads.

6. The semiconductor package of claim 5, wherein
the first connection pad and the third connection pads are output pads, and
the second connection pad and the fourth connection pads are input pads.

7. The semiconductor package of claim 3, wherein the second connection pad is spaced apart in a second direction from the fourth connection pads, the second direction being parallel to top surface of the film substrate and orthogonal to the first direction.

8. The semiconductor package of claim 7, wherein
the first connection pad and the third connection pads are output pads,
the second connection pad is a test pad, and
the fourth connection pads are input pads.

9. The semiconductor package of claim 3, further comprising:
a plurality of second wiring lines connected to the third connection pads; and
a plurality of second bumps between the second wiring lines and the active surface of the semiconductor chip.

10. The semiconductor package of claim 9, wherein the first wiring line is between adjacent ones of the second wiring lines.

11. The semiconductor package of claim 9, wherein the chip region includes a first region and a second region divided by the first wiring line,
wherein the second wiring lines are only on the first region.

12. The semiconductor package of claim 9, wherein
the first bump is spaced apart in the first direction from the second bumps, and
the first wiring line and the second wiring lines extend in a second direction parallel to the top surface of the film substrate and orthogonal to the first direction.

13. The semiconductor package of claim 5, further comprising:
a plurality of third wiring lines connected to the fourth connection pads; and
a plurality of third bumps between the third wiring lines and the semiconductor chip.

14. The semiconductor package of claim 13, wherein the first wiring line is between adjacent ones of the third wiring lines.

15. The semiconductor package of claim 14, wherein the chip region includes a first region and a second region divided by the first wiring line,
wherein the third wiring lines are only on the first region.

16. A semiconductor package, comprising:
a film substrate;
a semiconductor chip on the film substrate;
a first connection pad and a plurality of second connection pads on the film substrate and spaced apart from each other in a first direction parallel to the film substrate;
a first wiring line between the film substrate and the semiconductor chip and connected to the first connection pad;
a plurality of second wiring lines between the film substrate and the semiconductor chip and connected to the second connection pads; and
a first bump between the first wiring line and the semiconductor chip,
wherein the first wiring line includes a contact portion in contact with the first bump,
wherein the contact portion is between the second wiring lines,
wherein the contact portion includes:
a first portion;
a variable portion connected to the first portion and having variable thickness; and
a second portion connected to the variable portion and further away than the first portion from the first connection pad,
wherein a width of the second portion is greater than a width of the first portion.

17. The semiconductor package of claim 16, further comprising a second bump between the first wiring line and the semiconductor chip,
wherein the second bump is further away than the first bump from the first connection pad.

18. A package module, comprising:
a circuit substrate;
a display panel spaced apart from the circuit substrate; and
a semiconductor package between the circuit substrate and the display panel,
wherein the semiconductor package includes:
a semiconductor chip;
a film substrate including a chip region on which the semiconductor chip is disposed and an edge region surrounding the chip region;
a first connection pad and a plurality of second connection pads on the edge region and connected to the display panel;
a third connection pad on the edge region;
a plurality of fourth connection pads on the edge region and connected to the circuit substrate;
a first wiring line between the semiconductor chip and the film substrate and connected to the first connection pad and the third connection pad;
a plurality of second wiring lines between the semiconductor chip and the film substrate and connected to the second connection pads;
a plurality of third wiring lines between the semiconductor chip and the film substrate and connected to the fourth connection pads;
a first bump between the first wiring line and the semiconductor chip;
a plurality of second bumps between the second wiring lines and the semiconductor chip; and
a plurality of third bumps between the third wiring lines and the semiconductor chip,
wherein the first wiring line includes a contact portion in contact with the first bump,
wherein the contact portion includes:
a first portion; and
a second portion connected to the first portion and positioned further away from the first connection pad than is the first portion,
wherein a width of the second portion is greater than a width of the first portion.

19. The package module of claim 18, wherein the third connection pad is connected to the circuit substrate.

20. The package module of claim 18, wherein the third connection pad is a test pad.
